(19) United States
(12) Patent Application Publication
(10) Pub. No.: US 2017/0338137 A1
(43) Pub. Date: Nov. 23, 2017

(54) METHODS OF EVALUATING A PROCESS AND METHODS OF CONTROLLING A SUBSTRATE PROCESSING SYSTEM USING THE SAME

(71) Applicants: Gil-Su Son, Yongin-Si (KR); Dong-Sik Park, Suwon-Si (KR); Suho Jeong, Yongin-Si (KR); Kyungchun Lim, Suwon-Si (KR); Jungwook Kim, Seongnam-Si (KR); Minkyu Sohn, Suwon-Si (KR); Minwoo Lee, Hwaseong-Si (KR); Seungho Lee, Seongnam-Si (KR)

(72) Inventors: Gil-Su Son, Yongin-Si (KR); Dong-Sik Park, Suwon-Si (KR); Suho Jeong, Yongin-Si (KR); Kyungchun Lim, Suwon-Si (KR); Jungwook Kim, Seongnam-Si (KR); Minkyu Sohn, Suwon-Si (KR); Minwoo Lee, Hwaseong-Si (KR); Seungho Lee, Seongnam-Si (KR)

(21) Appl. No.: 15/461,740

(22) Filed: Mar. 17, 2017

(30) Foreign Application Priority Data
May 18, 2016 (KR) 10-2016-0061014

(51) Int. Cl. H01L 21/67

(52) U.S. Cl. CPC H01L 21/67253

(57) ABSTRACT

A method of evaluating a process of fabricating a semiconductor device includes obtaining measurement values from a plurality of sensors and predetermined reference values for each sensor, calculating, for each sensor, a measurement difference value between the reference value and the measurement value, calculating, for each sensor, a reference mean difference value between a maximum reference value for each sensor, which is greater than the reference value, and a minimum reference value for each sensor, which is less than the reference value, and dividing, for each sensor, the measurement difference value by the reference mean difference value to obtain a score value for each sensor.

### CROSS-REFERENCE TO RELATED APPLICATIONS

This U.S. non-provisional patent application claims priority under 35 U.S.C. §119 from, and the benefit of, Korean Patent Application No. 10-2016-0061014, filed on May 18, 2016 in the Korean Intellectual Property Office, the contents of which are herein incorporated by reference in their entirety.

### BACKGROUND

Embodiments of the present disclosure are directed to a method of controlling a substrate processing system, and in particular, to methods of evaluating a process of fabricating a semiconductor device and method of controlling a substrate processing system using the same.

A semiconductor device can be fabricated using a fabrication system with various sensors. The sensors provide various measurement data to a control unit. In general, based on the measurement data obtained by each of the sensors, the control unit can monitor the system used to fabricate the semiconductor device. Some of the measurement data is meaningful, but most of the data is meaningless.

Trend management is a method of interpreting data obtained from sensors. Trend management is performed based on a mean value of measurement data obtained by a sensor in a stabilized state. This method suffers from the following technical issues.

First, in the control unit, the same single standard is used to interpret measurement data obtained from all sensors. Intrinsic sensor characteristics are not considered in a process of interpreting the data. For example, although intrinsic characteristics of an open-loop control sensor and a closed-loop control sensor are different, data obtained by them are interpreted based on the same standard.

Second, in a semiconductor fabrication process, there is a transition period during which the sensors are not yet stabilized. Most of the measurement data obtained during the transition period are disused. For example, the control unit may discard measurement data obtained by a temperature sensor during a temperature-increasing period, when the fabrication system is controlled by the control unit.

Third, a measurement value obtained by a sensor may vary over time. For a normal sensor, it is challenging to apply such temporal variations to prepare the standard for a management.

The discarded measurement data does not represent variations in a process/system for fabricating a semiconductor device, and is not used in a prediction process based on correlation analyses between sensor measurement values and final products.

### SUMMARY

Exemplary embodiments of the inventive concept provide a process evaluation method that can compare measurement values of sensors with each other and a method of controlling a substrate processing system using the process evaluation method.

According to exemplary embodiments of the inventive concept, a method of evaluating a process includes obtaining a measurement value from a sensor of a substrate processing system during a semiconductor fabrication process and a predetermined reference value for the sensor, calculating a measurement difference value between the reference value and the measurement value, calculating a reference mean difference values between a maximum reference value for the sensor, which is greater than the reference value, and a minimum reference value for the sensor, which is less than the reference value, and dividing the measurement difference value by the reference mean difference value to obtain a score value for sensors. The score value is evaluated to determine whether to terminate the process

According to exemplary embodiments of the inventive concept, a method of controlling a substrate processing system includes performing a fabrication process on a substrate, obtaining monitoring data on the fabrication process, and evaluating the fabrication process using the monitoring data. Evaluating the fabrication process includes obtaining a measurement value from each of a plurality of sensors and predetermined reference values for each sensor, calculating a measurement difference value between the reference value and the measurement value for each sensor, calculating for each sensor a reference mean difference value between a maximum reference value for each sensor, which is greater than the reference value for each sensor, and a minimum reference value for each sensor, which is less than the reference value, and dividing for each sensor the measurement difference value by the reference mean difference value to obtain a score value for each sensor.

According to exemplary embodiments of the inventive concept, a method of evaluating a process includes obtaining a measurement value from each of a plurality of sensors and a predetermined reference value for each sensor, calculating a measurement difference value between the reference value and the measurement value for each sensor, calculating, for each sensor, a reference mean difference value between a maximum reference value for each sensor, which is greater than the reference value, and a minimum reference value for each sensor, which is less than the reference value, dividing, for each sensor, the measurement difference value by the reference mean difference value to obtain a score value for each sensor, comparing the generalized measurement values to each other to determine a ranking of the generalized measurement values, and displaying the score values in accordance with the rankings of the generalized measurement values.

### BRIEF DESCRIPTION OF THE DRAWINGS

FIG. 1 is a schematic diagram of a substrate processing system according to exemplary embodiments of the inventive concept.

FIG. 2 is a flow chart of a method of controlling a substrate processing system of FIG. 1.

FIG. 3 is a flow chart of an example of a process evaluation step of FIG. 2.

FIGS. 4A to 6A are graphs that show the first to third reference values, first to third measurement values, and first to third measurement difference values of first to third sensors of FIG. 1.

FIGS. 4B to 6B are graphs that show the first to third reference mean difference values of first to third sensors of FIG. 1.

FIG. 7 is a graph that shows the first to third score values of a first to third sensors of FIG. 1.

FIG. 8A is a graph that shows a fourth reference value, a fourth measurement value, and a fourth measurement difference value of a first sensor of FIG. 1.

FIG. 8B is a graph that shows a fourth reference mean difference value of a first sensor of FIG. 1.

FIG. 9 is a graph that shows a fourth score value of a first sensor of FIG. 1.

FIG. 10 is a graph that shows a fourth measurement value, a fourth maximum reference value, and a fourth, minimum reference value of FIGS. 8.A and 8B.

### DETAILED DESCRIPTION

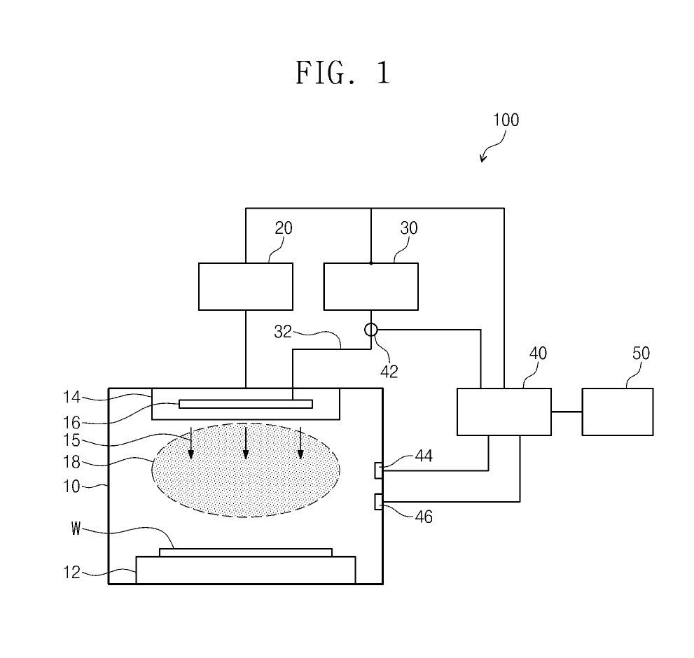

FIG. 1 is a schematic diagram of a substrate processing system 100 according to exemplary embodiments of the inventive concept.

Referring to FIG. 1, according to embodiments, the substrate processing system 100 is a plasma etching system. Alternatively, the substrate processing system 100 may be or further include one of a deposition system, a diffusion system, a thermal treatment system, a photolithography system, a polishing system, an ion injection system, a wet etching system, or a cleaning system. In exemplary embodiments, the substrate processing system 100 includes a chamber 10, a reaction gas supply unit 20, a radio frequency (RF) power supply unit 30, a control unit 40, first to third sensors 42, 44, and 46, and a display unit 50.

According to embodiments, chamber 10 provides an isolated space for performing a fabrication process on a substrate W. In exemplary embodiments, the chamber 10 includes an electrostatic chuck 12, a shower head 14, and a plasma electrode 16. The electrostatic chuck 12 is disposed at a lower region of the chamber 10. The substrate W is loaded on the electrostatic chuck 12. The shower head 14 is disposed at an upper region of the chamber 10. The shower head 14 can supply a reaction gas 15 onto the substrate W. The plasma electrode 16 is disposed in the shower head 14. The plasma electrode 16 can apply RE power to the reaction gas 15 in the chamber 10. The RF power can generate a plasma 18 from the reaction gas 15.

According to embodiments, the reaction gas supply unit 20 is connected to the shower head 14. The reaction gas supply unit 20 supplies the reaction gas 15 to the shower head 14. The reaction gas 15 contains a deposition gas or an etching gas. In exemplary embodiments, the reaction gas contains at least one of silane, hydrofluoric acid, carbonic acid, methane, chlorine, carbon tetrafluoride, or sulfuric acid.

According to embodiments, the RF power supply unit 30 is connected to the plasma electrode 16. The RF power supply unit 30 can apply RF power to the plasma electrode 16. The RF power is in a range of several kilowatts to several thousand kilowatts and a has frequency of several megahertz to several hundred megahertz.

According to embodiments, the control unit 40 controls the reaction gas supply unit 20 and the RF power supply unit 30. In exemplary embodiments, the control unit 40 includes a fault detection and classification (FDC) system. The control unit 40 is connected to the first to third sensors 42, 44, and 46. The control unit 40 uses sensing signals received from the first to third sensors 42, 44, and 46 to monitor a physical state of the chamber 10. In addition, the control unit 40 can evaluate a fabrication process being performed on the substrate W.

According to embodiments, the first to third sensors 42, 44, and 46 can be disposed in the chamber 10. Alternatively, the first to third sensors 42, 44, and 46 can be disposed outside the chamber 10. For example, the first sensor 42 can be an RF power sensor provided on a line 32 between the chamber 10 and the RF power supply unit 30. The second sensor 44 can be a vacuum sensor disposed in the chamber 10. The third sensor 46 can be a temperature sensor disposed in the chamber 10. The control unit 40 uses the sensing signals received from the first to third sensors 42, 44, and 46, respectively, to obtain information on the RF power, pressure, and temperature.

According to embodiments, the display unit 50 is connected to the control unit 40. The display unit 50 can display information on the RE power, pressure, and temperature. In addition, the display unit 50 can display a result of the evaluation.

The following are examples of methods of controlling the substrate processing system 100.

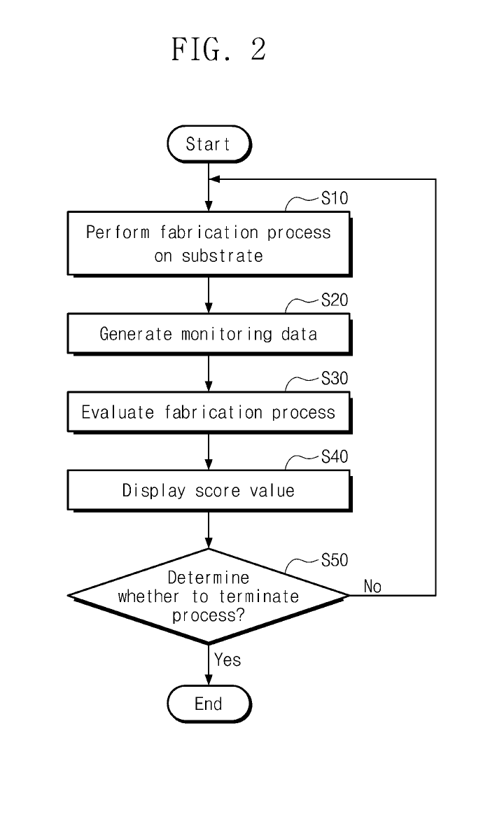

FIG. 2 is a flow chart of a method of controlling the substrate processing system 100 of FIG. 1.

Referring to FIG. 2, according to embodiments, a method of controlling the substrate processing system 100 includes performing a fabrication process on a substrate (step S10), monitoring the substrate processing system 100 to generate monitoring data (step S20), evaluating the fabrication process performed on the substrate (step S30), displaying a score value (step S40), and determining whether to terminate the fabrication process (step S50).

In detail, according to embodiments, the control unit 40 controls the reaction gas supply unit 20 and the RF power supply unit 30 to perform a fabrication process on a substrate W disposed in the chamber 10 (in S10).

Thereafter, according to embodiments, the control unit 40 receives first to third sensing signals from the first to third sensors 42, 44, and 46, and generates monitoring data on the substrate processing system 100 (step S20). The monitoring data contains measurement values. The control unit 40 can import reference values from a database.

Next, according to embodiments, based on the monitoring data, the control unit 40 evaluates the fabrication process, which is being performed on the substrate W (step S30). For example, the control unit 40 can compare the measurement values with the reference values to evaluate the fabrication process being performed by the substrate processing system on the substrate W.

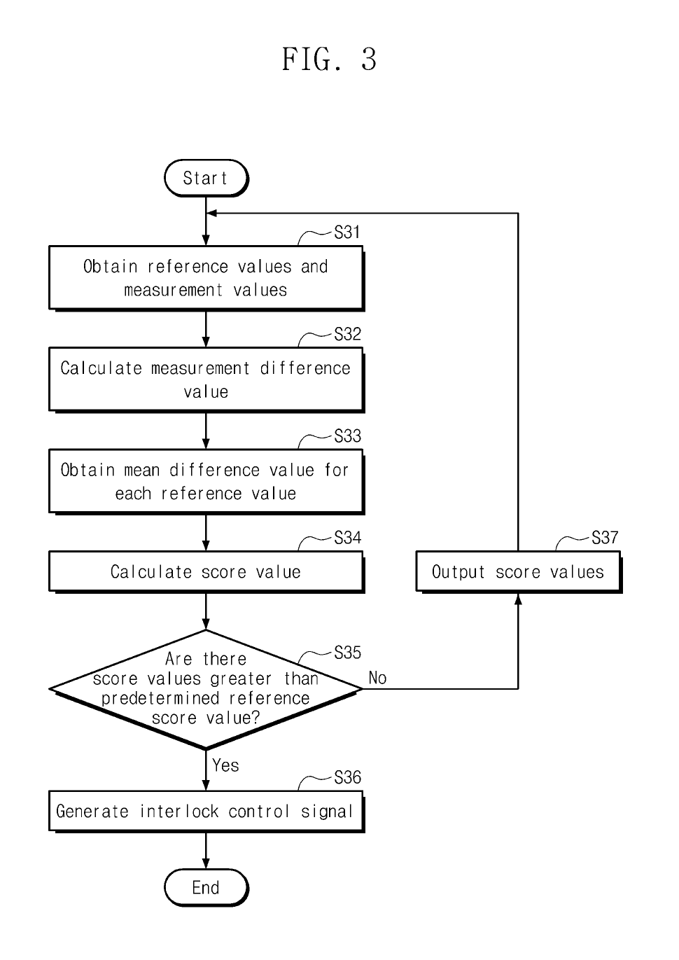

FIG. 3 illustrates an example of the evaluation step S30 of FIG. 2.

Referring to FIG. 3, according to embodiments, the evaluation step S30 includes obtaining reference values and measurement values (step S31), calculating a measurement difference value (step S32), obtaining a mean difference value for each of the reference values (step 533), calculating score values (step S34), comparing the score values with a predetermined reference score value (step S35), generating an interlock control signal, if the score values greater than the predetermined reference score value, (step S36), and outputting the score values, if the score values are not greater than the predetermined reference score value (step S37).

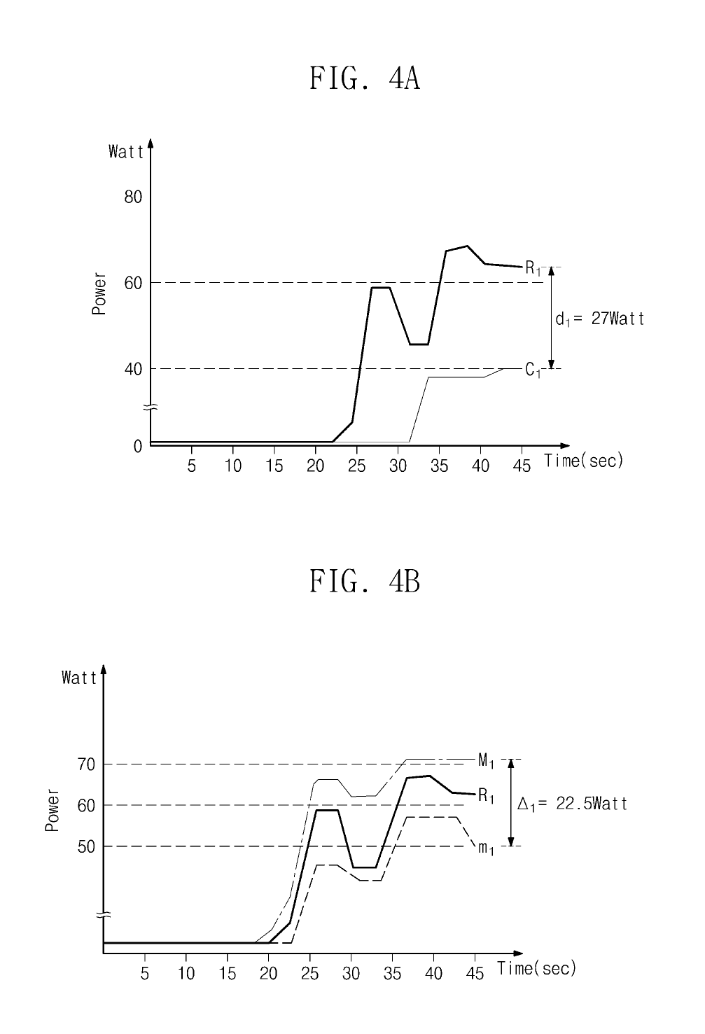

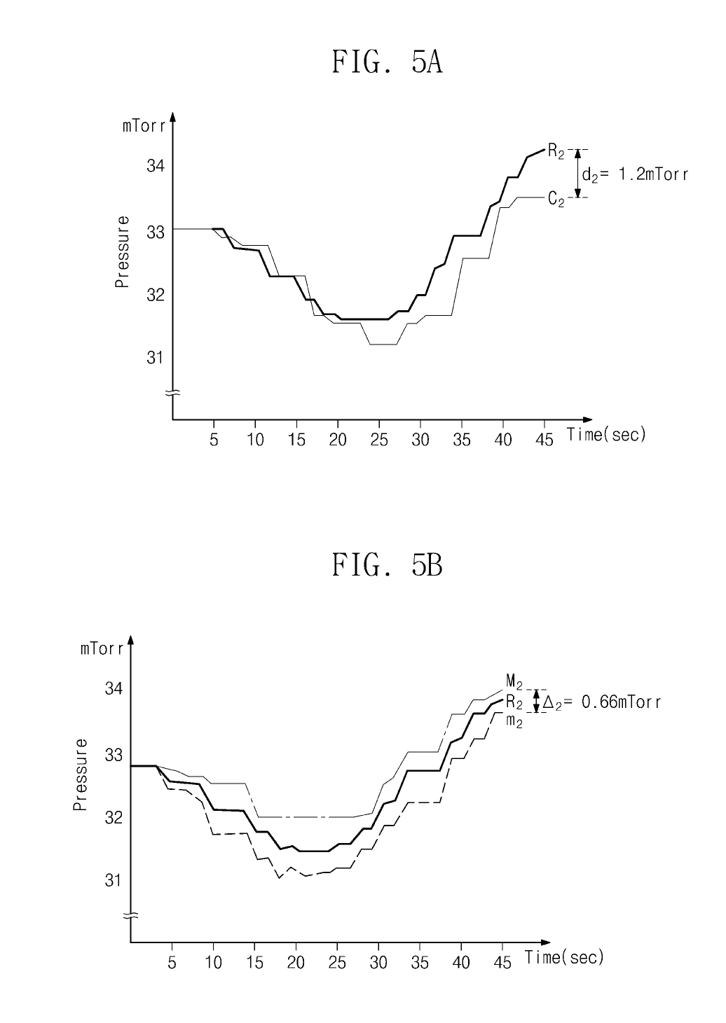

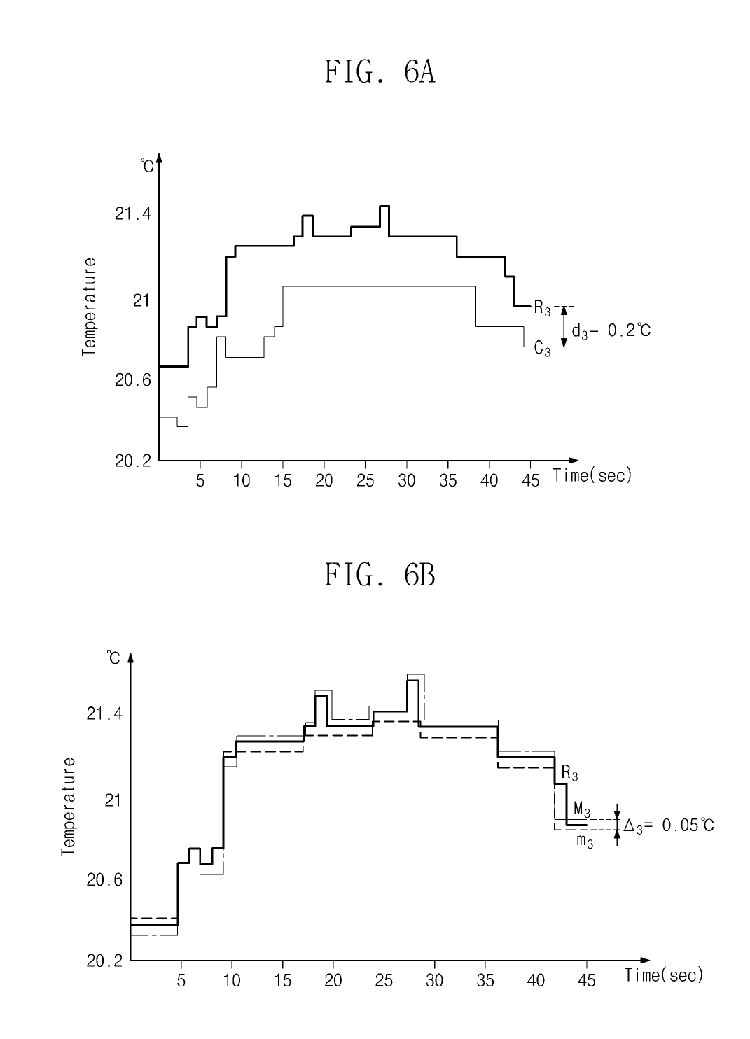

FIG. 4A shows a first reference value R₁ and a first measurement value C₁ of the first sensor 42 of FIG. 1. FIG. 5A shows a second reference value R₂ and a second measurement value C₂ of the second sensor 44 of FIG. 1. FIG. 6A shows a third reference value R₃ and a third measurement value C₃ of the third sensor 46 of FIG. 1. In the graphs of FIGS. 4A to 6A, the horizontal axis represents a process time.

Referring to FIGS. 3 and 4A to 6A, according to embodiments, the control unit 40 obtains measurement values of the first to third sensors 42, 44, and 46 and reference values (step S31). For example, the control unit 40 obtains the first to third measurement values C₁, C₂, and C₃ and the first to third reference values R₁, R₂, and R₃. The first to third measurement values C₁, C₂, and C₃ and the first to third reference values R₁, R₂, and R₃ can he obtained at a predetermined process time. An exemplary, non-limiting predetermined process time is about 45 seconds, however, embodiments are not limited thereto. The first measurement value C₁ is obtained from the sensing signal of the first sensor 42 during the fabrication process. The second measurement value C₂ is obtained from the sensing signal of the second sensor 44. The third measurement value C₃ is obtained from the sensing signal of the third sensor 46. The first to third reference values R₁, R₂, and R₃ have been selected and stored in advance before the fabrication process. For example, the first to third reference values R₁, R₂, and R₃ were previously measured in a normal fabrication process. In certain embodiments, the first to third measurement values C₁, C₂, and C₃ and the first to third reference values R₁, R₂, and R₃ can vary over time.

Next, according to embodiments, the control unit 40 obtains differences, hereinafter referred to as measurement difference values, between the measurement values and the reference values (step S32). In other words, the measurement difference values are given by a difference between the reference values and the measurement values. For example, the control unit 40 can calculate first to third measurement difference values d₁, d₂, and d₃, each of which is given by a difference between a corresponding pair of the first to third measurement values C₁, C₂, and C₃ and the first to third reference values R₁, R₂, and R₃. The first to third measurement difference values d₁, d₂, and d₃ can be calculated at a predetermined process time. An exemplary, non-limiting predetermined process time is about 45 seconds, however, embodiments are not limited thereto. The first measurement difference value d₁ is a difference between the first reference value R₁ and the first measurement value C₁. The second measurement difference value d₂ is a difference between the second reference value R₂ and the second measurement value C₂. The third measurement difference value d₃ is a difference between the third reference value R₃ and the third measurement value C₃.

FIG. 4B shows a first reference mean difference value Δ₁ of the first sensor 42 of FIG. 1. FIG. 5B shows a second reference mean difference value Δ₂ of the second sensor 44 of FIG. 1. FIG. 6B shows a third reference mean difference value Δ₃ of the third sensor 46 of FIG. 1. In the graphs of FIGS. 4B to 6B, the horizontal axis represent a process time.

Referring to FIGS. 3 and 4B to 6B, according to embodiments, the control unit 40 obtains reference mean difference values (step S33). The reference mean difference value is a difference between the highest and lowest reference values. For example, the control unit 40 can calculate first to third reference mean difference values Δ₁, Δ₂, and Δ₃. The first to third reference mean difference values Δ₁, Δ₂, and Δ₃ are calculated at a predetermined process time. An exemplary, non-limiting predetermined process time is about 45 seconds, however, embodiments are not limited thereto. The first reference mean difference value Δ₁ is obtained by subtracting a first minimum reference value m₁ from a first maximum reference value M₁. The first reference value R₁ is a mean value of the first maximum reference value M₁ and the first minimum reference value m₁. The second reference mean difference value Δ₂ is obtained by subtracting a second minimum reference value m₂ from a second maximum reference value M₂. The second reference value R₂ is a mean value of the second maximum reference value M₂ and the second minimum reference value m₂. The third reference mean difference value Δ₃ is obtained by subtracting a second minimum reference value m₃ from a third maximum reference value M₃. The third reference value R₃ is a mean value of the third maximum reference value M₃ and the second minimum reference value m₃.

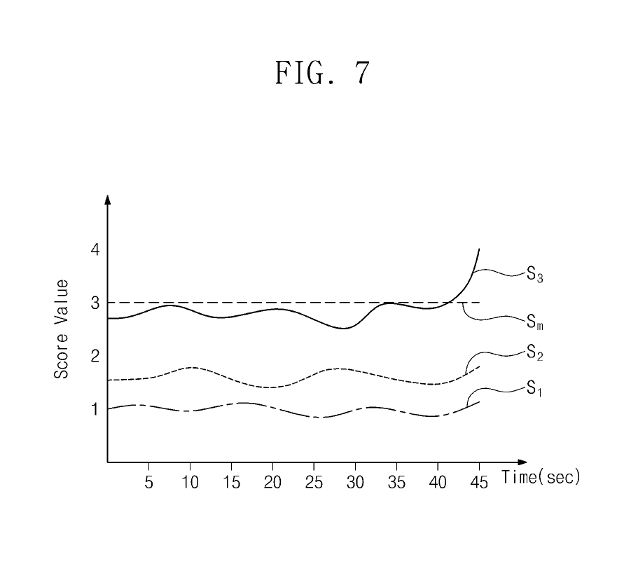

FIG. 7 shows the first to third score values S₁, S₂, and S₃ of the first to third sensors 42, 44, and 46 of FIG. 1.

Referring to FIGS. 3 and 7, according to embodiments, the control unit 40 divides the measurement difference values by the reference mean difference values to calculate score values (step S34). For example, the control unit 40 divides the first to third measurement difference values d₁, d₂, and d₃ by the first to third reference mean difference values Δ₁, Δ₂, and Δ₃, respectively, to calculate the first to third score values S₁, S₂, and S₃ of the first to third sensors 42, 44, and 46. The first to third score values S₁, S₂, and S₃ are calculated at a predetermine process time. An exemplary, non-limiting predetermined process time is about 45 seconds, however, embodiments are not limited thereto. The first score value S₁ may be about 1.2. The second score value S₂ may be about 1.8. The third score value S₃ may be about 4.

Next, according to embodiments, the control unit 40 compares the score values with predetermined reference score value Sₘ (step S35). The reference score value Sₘ can be statistically determined, based on a standard deviation, such as 3σ, of the process. Alternatively, the reference score value Sₘ may he predetermined. For example, the reference score value Sₘ may be 3. Each of the first to third score values S₁, S₂, and S₃ is individually compared with the reference score value Sₘ.

According to embodiments, if at least one of the score values is greater than the reference score value Sₘ, the control unit 40 generates an interlock control signal (step S36). For example, the third score value S₃ can be greater than the reference score value Sₘ. In this case, the control unit 40 causes the display unit 50 to display check items associated with the temperature of the chamber 10. In addition, the display unit 50 displays that the RF power and the vacuum is in a normal state.

According to embodiments, if all of the score values are less than the reference score value Sₘ, the control unit 40 outputs the score values to the display unit 50 (step S37). The first to third score values S₁, S₂, and S₃ are provided to the display unit 50.

Referring back to FIGS. 2 and 7, according to embodiments, the display unit 50 displays the score values (step S40). In exemplary embodiments, the first to third score values S₁, S₂ and S₃ correspond to generalized measurement values of the first to third sensors 42, 44, and 46. That is, the control unit 40 treats or interprets the first to third score values S₁, S₂, and S₃ as the generalized measurement values of the first to third sensors 42, 44, and 46. The first to third score values S₁, S₂, and S₃ can be compared with each other. For example, the first score value S₁ may be less than the second score value S₂. The second score value S₂ may be less than the third score value S₃. The control unit 40 causes the display unit 50 to display the first to third score values S₁, S₂, and S₃.

Furthermore, according to embodiments, the control unit 40 compares the first to third score values S₁, S₂, and S₃ with each other to determine the rankings of the generalized measurement values. The display unit 50 displays the first to third score values S₁, S₂, and S₃, in accordance with the rankings of the generalized measurement values, at a predetermined process time. An exemplary, non-limiting predetermined process time is about 45 seconds, however, embodiments are not limited thereto. The displayed first to third score values S₁, S₂, and S₃ are check items associated with the first to third sensors 42, 44, and 46. For example, check items associated with the temperature may be displayed as the highest ranking issue. Check items associated with the vacuum level may be displayed as an intermediate ranking issue. Check items associated with the RF power may be displayed as the lowest ranking issue. This can improve the reliability of a process of fabricating a semiconductor device.

Next, according to embodiments, the control unit 40 determines whether to terminate the fabrication process (step S50). If there is no need to terminate the fabrication process, the afore-described steps S10 to S40 are performed again under the control of the control unit 40.

If it is necessary to terminate the fabrication process, the control of the substrate processing system 100 ends.

The evaluation step S30 according to exemplary embodiments of the inventive concept can be performed during a process time interval,

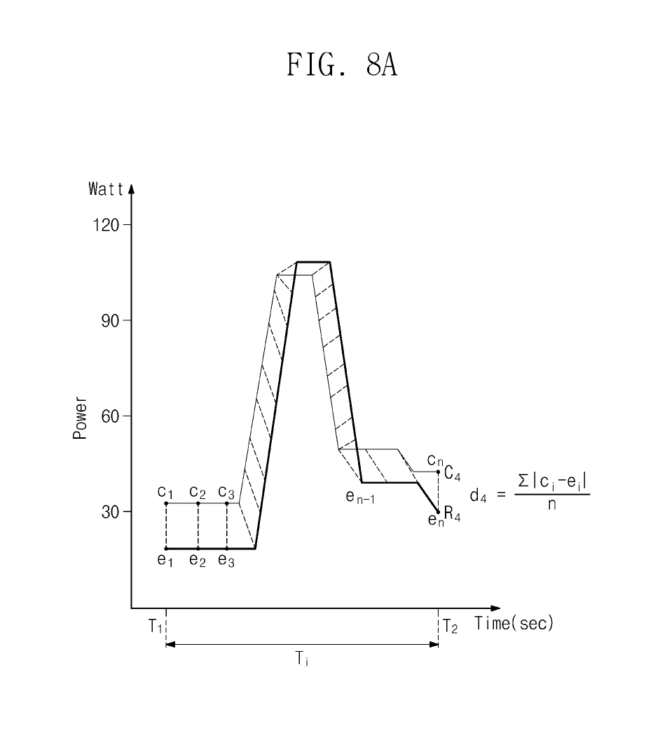

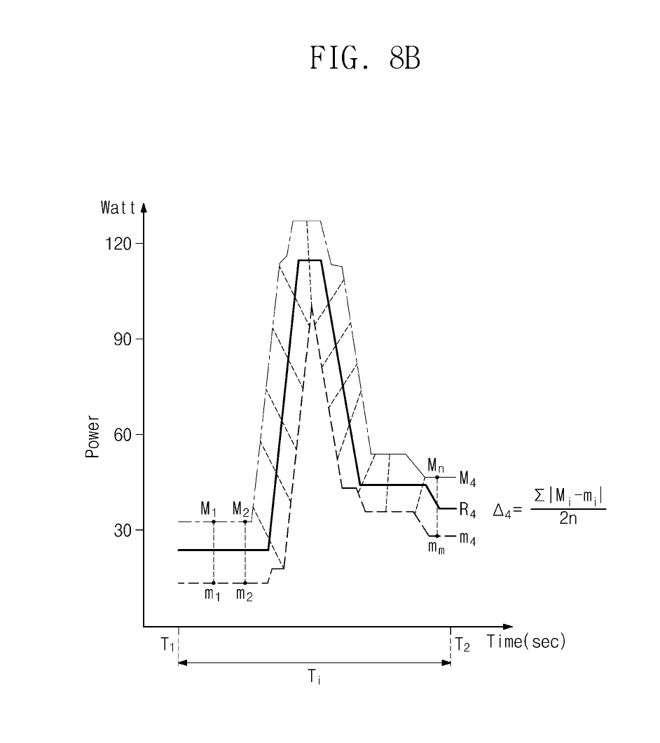

FIG. 8A is a graph that shows a fourth reference value R₄, a fourth measurement value C₄, and a fourth measurement difference value d₄ of the first sensor 42 of FIG. 1.

Referring to FIGS. 3 and 8A, according to embodiments, during a process time interval, the control unit 40 obtains a plurality of measurement values and reference values for each sensor (step S31). For example, a first process time interval T₁ can be a time interval from a first process time T₁ to a second process time T₂. The control unit 40 obtains a fourth measurement value C₄ and a fourth reference value R₄ for the first process time interval T₁.

According to embodiments, the fourth measurement value C₄ includes first to n-th unit measurement values c₁-cₙ. The first to n-th unit measurement values c₁-cₙ are obtained during the first process time interval T₁.

According to embodiments, the fourth reference value R₄ includes first to n-th unit reference values e₁-eₙ. The first to n-th unit reference values e₁-eₙ are obtained during the first process time interval T₁.

Next, according to embodiments, the control unit 40 obtains a measurement difference value for one of the sensors for the process time interval (step S32). For example, the control unit 40 obtains a fourth measurement difference value d₄ for the first process time interval T₁. The fourth measurement difference value d₄ is obtained by dividing the sum of absolute values, i.e., |c₁-eᵢ|, of differences between the first to n-th unit measurement values c₁-cₙ and the respective first to n-th unit reference values eⱼ-eₙ by the measurement number n. In the graph of FIG. 8A, the sum of the absolute values of the differences between the first to n-th unit measurement values c₁-cₙ and the first to n-th unit reference values e₁-eₙ corresponds to an area between the first to n-th unit measurement values c₁-cₙ and the first to n-th unit reference values e₁-eₙ. That is, the fourth measurement difference value d₄ is a unit measurement difference value between the first to n-th unit measurement values c₁-cₙ and the first to n-th unit reference values e₁-eₙ.

FIG. 8B is a graph that shows a fourth reference mean difference value Δ₄ of the first sensor 42 of FIG. 1.

Referring to FIGS. 3 and 8B, according to embodiments, the control unit 40 obtains a reference mean difference value for each sensor for the process time interval (step S33). For example, the control unit 40 obtains a fourth reference mean difference value Δ₄ for one of the sensors for the first process time interval T₁. The fourth reference value R₄ is between a fourth maximum reference value M₄ and a fourth minimum reference value m₄. The fourth maximum reference value M₄ includes first to n-th maximum unit reference values M₁-Mₙ. The fourth minimum reference value m₄ includes first to n-th minimum unit reference values m₁-mₙ. The fourth reference mean difference value Δ₄ is obtained by dividing the sum of absolute values, i.e., |M₁-m₁|, of differences between the first to n-th maximum unit reference values M₁-Mₙ and the first to n-th minimum unit reference values m₁-mₙ by the measurement number n and the factor of 2. In the graph of FIG. 8B, the sum of the absolute values |M₁-m₁| of differences between the first to n-th maximum unit reference values M₁-Mₙ and the first to n-th minimum unit reference values m₁-mₙ corresponds to an area between the first to n-th maximum unit reference values M₁-Mₙ and the first to n-th minimum unit reference values m₁-mₙ. By dividing with the factor of 2, the fourth reference mean difference value Δ₄ corresponds to half the area between the first to n-th maximum unit reference values M₁-Mₙ and the first to n-th minimum unit reference values. In other words, the fourth reference mean difference value Δ₄ corresponds to half a unit reference mean difference value between the first to n-th maximum unit reference values M₁-Mₙ and the first to n-th minimum unit reference values.

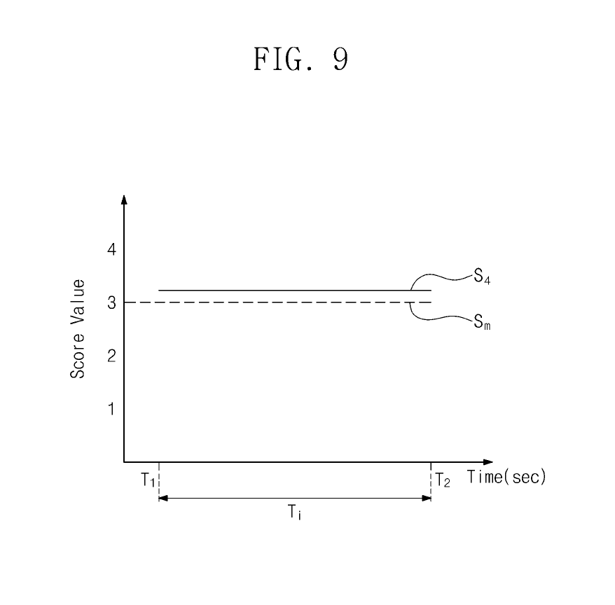

FIG. 9 is a graph that shows a fourth score value S4 of the first sensor 42 of FIG. 1.

Referring to FIGS. 3 and 9, according to embodiments, the control unit 40 calculates a score value for the process time interval (in S34). For example, a fourth score value S₄ can be calculated by dividing the fourth measurement difference value d₄ by the fourth reference mean difference value Δ₄. In exemplary embodiments, the fourth score value S₄ may be about 3.2.

Next, according to embodiments, the control unit 40 compares the score value for the process time interval with a predetermined reference score value Sₘ (step S35). For example, the control unit 40 compares the fourth score value S₄ with the reference score value Sₘ.

If the fourth score value S₄ is greater than the reference score value Sₘ, the control unit 40 outputs an interlock control signal (step S36).

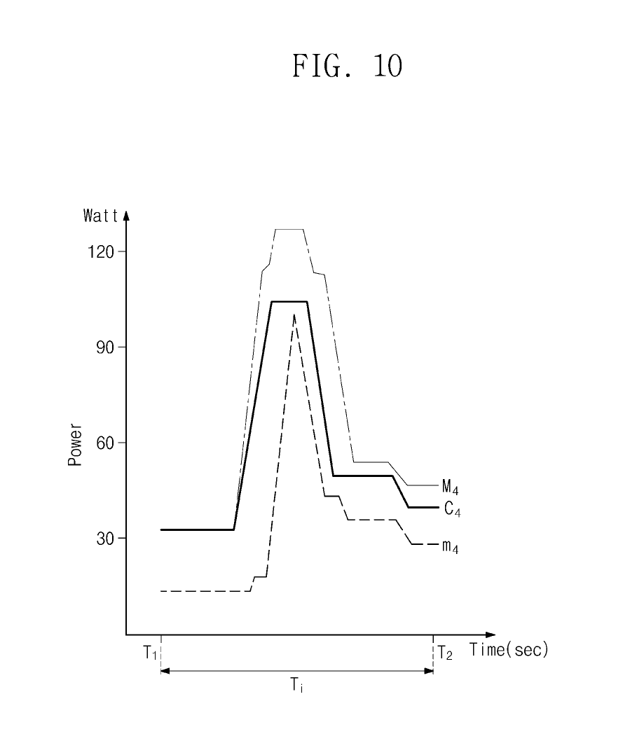

FIG. 10 is a graph that shows the fourth measurement value C₄, the fourth maximum reference value M₄, and the fourth minimum reference value m₄ of FIGS. 8A and 8B.

Referring to FIG. 10, according to embodiments, the fourth measurement value C₄ may be less than the fourth maximum reference value M₄ and greater than the fourth minimum reference value m₄. In general, the fourth measurement value C₄ is not displayed. The fourth score value S₄ corresponds to a total variation of the fourth measurement value C₄. If there is a large variation of the fourth measurement value C₄, the fourth score value S₄ may be higher than the reference score value Sₘ. Depending on the fourth score value S₄, the control unit 40 may generate an interlock control signal. The control unit 40 can maximally increase reliability of the fabrication process, based on the fourth score value S₄ for the process time interval.

If the fourth score value S₄ is less than the reference score value Sₘ, the control unit 40 outputs the fourth score value S₄ to the display unit 50 (in S37).

According to exemplary embodiments of the inventive concept, a process evaluation method includes dividing measurement difference values, which are given by differences between measurement values and reference values, by reference mean difference values to calculate score values of measurement values of sensors. The score values are generalized values of the measurement values. The generalized measurement values are compared with each other.

While exemplary embodiments of the inventive concepts have been particularly shown and described, it will be understood by one of ordinary skill in the art that variations in form and detail may be made therein without departing from the spirit and scope of the attached claims.

What is claimed is:

1. A method of evaluating a process, comprising:
obtaining a measurement value from a sensor of a substrate processing system during a semiconductor fabrication process and a predetermined reference value for the sensor;
calculating a measurement difference value between the reference value and the measurement value;
calculating a reference mean difference value between a maximum reference value for the sensor, which is greater than the reference value for the sensor, and a minimum reference value for the sensor, which is less than the reference value for the sensor; and
dividing the measurement difference value by the reference mean difference value to obtain a score value fur the sensor,
wherein the score value is evaluated to determine whether to terminate the process.

2. The method of claim 1, further comprising comparing the score value with a predetermined reference score value for the sensor.

3. The method of claim 2, further comprising generating an interlock control signal, when the score value is greater than the reference score value.

4. The method of claim 1, wherein the reference value is obtained from a mean value between the maximum reference value and the minimum reference value.

5. The method of claim 1, wherein the measurement value for the sensor comprises first to n-th unit measurement values obtained during a process time interval from a first process time to a second process time, and
the reference value for the sensor comprises first to n-th unit reference values for the process time interval.

6. The method of claim 5, wherein the measurement difference value is obtained by dividing a sum of an absolute value of a difference between the first to n-th unit measurement values and the respective first to n-th unit reference values by the number of measurements performed.

7. The method of claim 1, wherein the maximum reference value for the sensor comprises first to n-th maximum unit reference values for a process time interval from a first process time to a second process time, and
the minimum reference value comprises first to n-th minimum unit reference values for the process time interval.

8. The method of claim 7, wherein the reference mean difference value is obtained by dividing a sum of absolute values of differences between the first to n-th maximum unit reference values and the respective first to n-th minimum unit reference values by the number of measurements performed and a constant number.

9. The method of claim 8, wherein the constant number is 2.

10. A method of controlling a substrate processing system, comprising:
performing a fabrication process on a substrate;
obtaining monitoring data on the fabrication process; and
evaluating the fabrication process using the monitoring data,
wherein evaluating the fabrication process comprises:
obtaining a measurement value from each of a plurality of sensors and a predetermined reference value for each sensor;
calculating a measurement difference value between the reference value and the measurement value for each sensor;
calculating, for each sensor, a reference mean difference value between a maximum reference value for each sensor, which is greater than the reference value, and a minimum reference value for each sensor, which is less than the reference value; and
dividing, for each sensor, the measurement difference value by the reference mean difference value to obtain a score value for each sensor.

11. The method of claim 10, wherein the substrate processing system comprises:
a control unit;
a chamber in which the fabrication process is performed; and
a plurality of sensors connected to the control unit and provided between the control unit and the chamber,
wherein each score values is calculated as a generalized measurement value for each. sensor.

12. The method of claim 11, further comprising:
comparing the generalized measurement values to each other to determine a ranking of the generalized measurement values; and
displaying the score values in accordance with the rankings of the generalized measurement values.

13. The method of claim 11, wherein the substrate processing system further comprises a display unit connected to the control unit, and
evaluating the fabrication process further comprises:
comparing each score value with a predetermined reference score value for each sensor; and
outputting the score values to the display unit, when a score value for a sensor is less than the reference score value for the sensor.

14. The method of claim 10, further comprising displaying the score value for each sensor,
wherein the score values are displayed based on a comparison with each other.

15. A method of evaluating a process, comprising;
obtaining a measurement value from each of a plurality of sensors and a predetermined reference value for each sensor;
calculating a measurement difference value between the reference value and the measurement value for each sensor;
calculating, for each sensor, a reference mean difference value between a maximum reference value for each sensor, which is greater than the reference value, and a minimum reference value for each sensor, which is less than the reference value;
dividing, for each sensor, the measurement difference value by the reference mean difference value to obtain a score value for each sensor;
comparing the generalized measurement values to each other to determine a ranking of the generalized measurement values; and
displaying the score values in accordance with the rankings of the generalized measurement values.

16. The method of claim 15, wherein the measurement value for each sensor comprises first to n-th unit measurement values for each sensor obtained during a process time interval from a first process time to a second process time, and
the reference value for each sensor comprises first to n-th unit reference values for each sensor for the process time interval.

17. The method of claim 16, wherein the measurement difference value for each sensor is obtained by dividing a sum of an absolute value of a difference between the first to n-th unit measurement values for each sensor and the respective first to n-th unit reference values for each sensor by the number of measurements performed.

18. The method of claim 15, wherein the maximum reference value for each sensor comprises first to n-th maximum unit reference values for each sensor for a process time interval from a first process time to a second process time, and
the minimum reference value for each sensor comprises first to n-th minimum unit reference values for each sensor for the process time interval.

19. The method of claim 18, wherein the reference mean difference value for each sensor is obtained by dividing a sum of absolute values of differences between the first to n-th maximum unit reference values for each sensor and the respective first to n-th minimum unit reference values for each sensor by the number of measurements performed and a constant number.

20. The method of claim 19, wherein the constant number is 2.
